(19) United States
(12) Patent Application Publication
(10) Pub. No.: US 2011/0067850 A1
(43) Pub. Date: Mar. 24, 2011

(54) Buckling Device with Cooling Function

(76) Inventors: George Anthony Meyer, IV, San Jose, CA (US); Chien-Hung Sun, Zhongli City (TW); Chieh-Ping Chen, Zhongli City (TW)

(21) Appl. No.: 12/563,550

(22) Filed: Sep. 21, 2009

(51) Int. Cl. F28F 7/00; H05K 7/20

(52) U.S. Cl. 165/185

(57) ABSTRACT

A buckling device for electronic heating element, inter-assembled with a thermally conductive body, includes a cooling plate, a pair of fixing legs bent-and-extended from the cooling plate and formed under the cooling plate and a fixing arm bent-and-extended from the cooling plate and formed under the cooling plate. On the cooling plate, a plurality of slots are stamped, one side of each of which is bent and configured into a cooling piece. The thermally conductive body is fixed by being sandwiched between the fixing arm and the cooling plate. Thereby, the buckling device can be used in a thin electronic device to reduce its assembly and machining costs on a large scale.

### BACKGROUND OF THE INVENTION

1. Field of the Invention

The present invention in general relates to a buckling device, in particular, to a buckling device with cooling function for electronic heating element.

2. Description of Prior Art

Following the progress and development of informational technology, a variety of electronic elements, for example, CPU, IC component, power transistor, etc., have a working speed increasing day by day. Therefore, when they are operating or executing in high speed, a large amount of heat is frequently generated. If the heat is not dissipated in time, the normal operation of the electronic elements will be influenced. For example, their executing speeds are slowed down. Furthermore, the hardware or facility even could be damaged, causing a short lifespan of usage.

In addition, in order to carry the devices or products composed of aforementioned electronic elements in a more convenient way, the manufacturers all beat their brains to design their products with the merits of lightness, thinness, shortness and smallness, to thereby fulfill the prevalent requirement in the market. Therefore, how to design an electronic product simultaneously fulfilling the market requirement and possessing excellent cooling function has become an important issue intended to be addressed by the inventor.

According to prior arts, a cooling structure of electronic heating device mostly is to use a buckling device to confine a cooler of aluminum extrusion type or stack type. Then, the cooler is installed onto an electronic heating element and dissipates the heat generated therefrom. By so doing, the buckling device has an assembling function fulfilled between the cooler and the peripheral components of the electronic heating element.

However, in terms of practical use, the cooling structure for electronic heating elements according to the prior arts still has several drawbacks as the following. First of all, since these coolers must be configured with a specific thickness, so it is impossible to fulfill the using requirement asked by current product, which has a trend of thin thickness. In addition, its cooler and buckling device have to be manufactured under different molds, which only wastes manufacturing cost due to the additional molds. Furthermore, after being manufactured, the cooler and buckling device still have to be assembled together, which increases the assembling cost additionally. All of aforementioned drawbacks are needed to be solved urgently.

Accordingly, after a substantially devoted study, in cooperation with the application of relative academic principles, the inventor has finally proposed the present invention designed reasonably to possess the capability to improve the drawbacks of the prior art significantly.

### SUMMARY OF THE INVENTION

Therefore, in order to solve aforementioned problems, the invention is mainly to provide an buckling device with cooling function. The invention is inter-assembled with a thermally conductive body and includes a cooling plate, at least one pair of fixing legs bent-and-extended from the cooling plate and formed under the cooling plate and at least one fixing arm bent-and-extended from the cooling plate and formed under the cooling plate. On the cooling plate, a plurality of slots are stamped, and one side of each slot is bent and formed into a cooling piece. The thermally conductive body is fixed by being sandwiched between the fixing arm and the cooling plate.

Furthermore, the invention has following functions and merits. Since the cooling pieces and the fixing legs are directly arranged on the cooling plate, there is no waste generated, such that the material cost is lowered down on a large scale. Secondary, after being integrated with the thermally conductive body, the invention can directly be provided for cooling the electronic heating element, thereby, the assembly cost with respect to the cooling body being able to be saved.

### BRIEF DESCRIPTION OF DRAWING

The features of the invention believed to be novel are set forth with particularity in the appended claims. The invention itself, however, may be best understood by reference to the following detailed description, which describes a number of embodiments of the invention, taken in conjunction with the accompanying drawings, in which:

FIG. 1 is a perspective outer illustration of a buckling device according to the present invention;

FIG. 2 is an assembled illustration of the thermally conductive body and the buckling device according to the present invention;

FIG. 3 is an illustration of FIG. 2 viewed from another angle;

FIG. 4 is a sectional view of FIG. 3; and

FIG. 5 is an assembled sectional view of the thermally conductive body and the buckling device according to the invention applied in a heating element.

### DETAILED DESCRIPTION OF THE INVENTION

In cooperation with attached drawings, the technical contents and detailed description of the present invention are described thereinafter according to a number of embodiments, not used to limit its executing scope. Any equivalent variation and modification made according to appended claims is all covered by the claims claimed by the present invention.

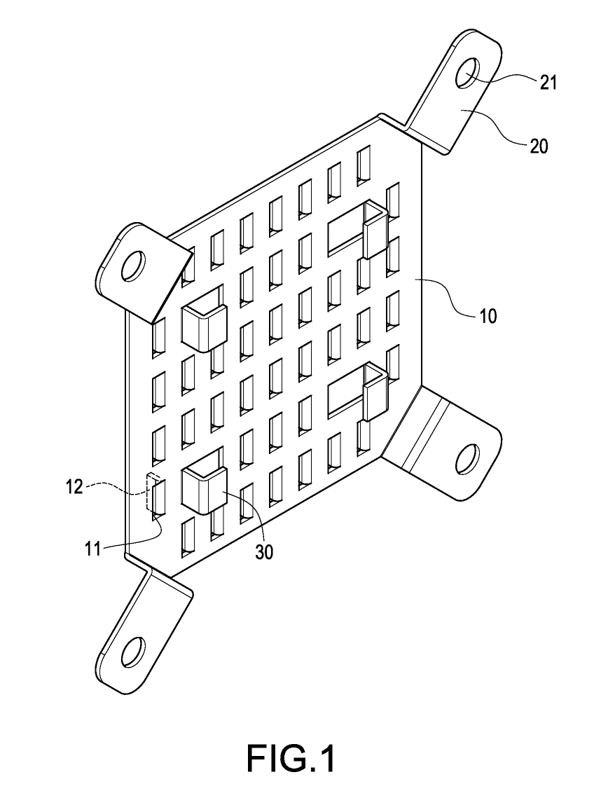

As shown in FIG. 1, the invention is to provide a buckling device having cooling function, mainly including a cooling plate 10 constructed as one body, two pairs of fixing legs 20 and four pieces of fixing arms 30. This kind of buckling device is made of materials possessing excellent cooling characteristics, such as, aluminum, copper, etc. The cooling plate 10 is substantially shown as a quadrilateral configuration, on which a plurality of slots 11 are stamped, one side of each of which is bent and configured into a cooling piece 12, all of which are formed above the cooling plate 10. These four pieces of fixing legs 20 are formed by being bent downwardly from four corners of the cooling plate 10 and are substantially shown as an “L” shape separately. Meanwhile, a perforation 21 is arranged on each fixing legs 20. These four pieces of fixing arms 30 are also formed by being bent downwardly from the cooling plate 10 and are substantially shown as an “L” shape separately. These fixing arms 30 and the cooling pieces 12 are respectively located at oppositely upper and lower sides of the cooling plate 10.

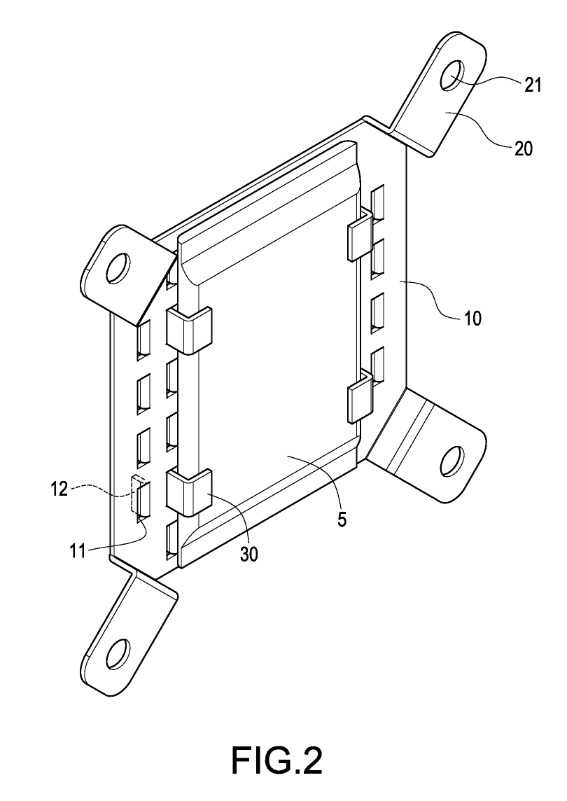

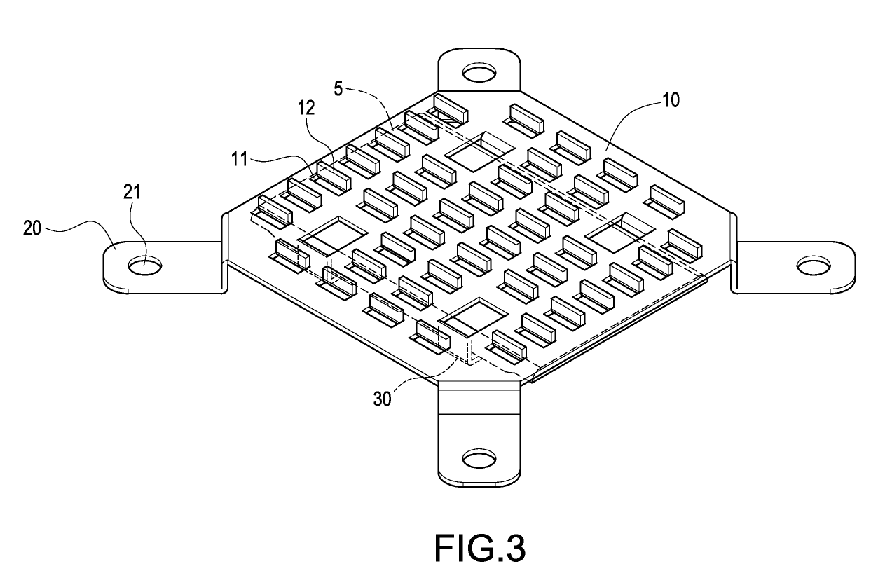

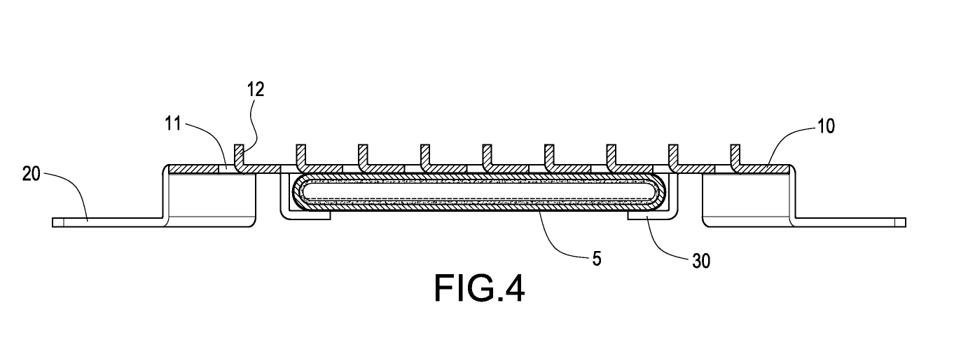

Please refer to FIG. 2 through FIG. 4. The buckling device according to the invention can be inter-assembled with a thermally conductive body 5. In this case, the thermally conductive body 5 is a vapor chamber. However, it can also be a heat pipe. This thermally conductive body 5 has a vacuum chamber, an interior of which is disposed a capillary structure made of porous materials and is filled with a working fluid. Through phase changes of this kind of working fluid, a rapidly thermal conduction can be achieved. In the vapor chamber, through the capillary absorption of the capillary structure, the condensed liquid flows back to the heated portion, in order to constitute a continuously thermal circulation. Through each fixing arms 30, this thermally conductive body 5 is fixed by being clamped onto the bottom face of the cooling plate 10. In the meantime, a thermally conductive paste (not shown in the figures) can be coated between the thermally conductive body 5 and the cooling plate 10, whereby a closely contacting effect can be enhanced between the thermally conductive body 5 and the cooling plate 10.

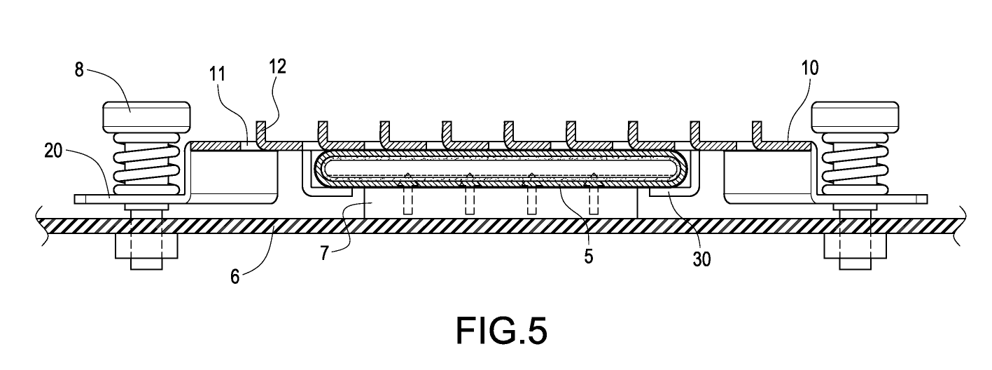

Please refer to FIG. 5, showing that the buckling device of the invention can be provided to an electronic heating element 7 (e.g., processor or chip) to process a cooling procedure. In this case, the electronic heating element 7 is fixed onto a circuit board 6 and a plurality of pre-designed holes are arranged on the circuit board 6 by surrounding the electronic heating element 7. When using, the bottom face of the thermally conductive body 5 is attached onto the upper surface of the electronic heating element 7. In turn, screwing elements 8 are provided to pass through the perforations 21 of each fixing legs 20 and the pre-designed holes of the circuit board 6, whereby the buckling device of the invention is fixed onto the circuit board 6, making a direct heat transfer fulfilled between the thermally conductive body 5 and the electronic heating element 7.

Accordingly, through the constitution of aforementioned assemblies, a buckling device having cooling function according to the invention is thus obtained.

Summarizing aforementioned description, the buckling device having cooling function is an indispensably design for electronic heating elements indeed, which may positively reach the expected usage objective for solving the drawbacks of the prior arts, and which extremely possesses the innovation and progressiveness to completely fulfill the applying merits of a new type patent, according to which the invention is thereby applied. Please examine the application carefully and grant it as a formal patent for protecting the rights of the inventor.

However, the aforementioned description is only a number of preferable embodiments according to the present invention, not used to limit the patent scope of the invention, so equivalently structural variation made to the contents of the present invention, for example, description and drawings, is all covered by the claims claimed thereinafter.

What is claimed is:

1. A buckling device having cooling function, inter-assembled with a thermally conductive body and including a cooling plate, at least one pair of fixing legs bent-and-extended from the cooling plate and formed under the cooling plate and at least one fixing arm bent-and-extended from the cooling plate and formed under the cooling plate, on the cooling plate, a plurality of slots being stamped, one side of each of which is bent and formed into a cooling piece, the thermally conductive body being fixed and sandwiched between the fixing arm and the cooling plate.

2. The buckling device according to claim 1, wherein the cooling plate, the pair of fixing legs and the fixing arm are constructed as one body.

3. The buckling device according to claim 2, wherein the buckling device is made of an aluminum material.

4. The buckling device according to claim 2, wherein the buckling device is made of a copper material.

5. The buckling device according to claim 1, wherein the cooling plate is formed as a quadrilateral configuration, from four corners of which the pair of fixing legs are bent and formed.

6. The buckling device according to claim 5, wherein the fixing legs are configured as an “L” shape separately, at a longer side of which a perforation is arranged.

7. The buckling device according to claim 1, wherein the fixing arm and the cooling pieces are located at two opposite sides of the cooling plate.

8. The buckling device according to claim 1, wherein the arm is configured as an “L” shape.
